(19) United States
(12) Patent Application Publication
(10) Pub. No.: US 2023/0152238 A1
(43) Pub. Date: May 18, 2023

(54) MULTIPLE STRIP READER

(71) Applicant: James B. Babcock, Phoenix, MD (US)

(72) Inventor: James B. Babcock, Phoenix, MD (US)

(21) Appl. No.: 17/988,042

(22) Filed: Nov. 16, 2022

Related U.S. Application Data
(60) Provisional application No. 63/279,726, filed on Nov. 16, 2021.

(51) Int. Cl. G01N 21/84; G01N 21/78; H01L 27/146

(52) U.S. Cl. CPC G01N 21/8483; G01N 21/78; H01L 27/14643

(57) ABSTRACT

An improved test-strip reader with multi-strip loading carriage capable of loading a plurality of test strips at once and automatically identifying them, referencing their positions, cataloguing/indexing them, calibrating them, imaging them, and correcting and analyzing them. The loading carriage has a plurality of imaging beds to seat and position individual strips, and a clamping mechanism to affix them therein. When the user places the test strips in the carriage and initiates insertion into the enclosure, a latch maintains position, and the remainder of the imaging and analysis process is completed automatically with an internal imaging assembly. The apparatus makes it possible to measure various reagents at once including Free Chlorine (FC), total alkalinity (TA), cyanuric acid (CYA), total chlorine (TC), bromine (Br), and pH as typical of a pool or spa. It further maximizes ease and efficiency of use and minimizes risk of user error.

### CROSS-REFERENCE TO RELATED APPLICATION(S)

The present application derives priority from U.S. provisional application Ser. No. 63/279,726 filed Nov. 16, 2021.

### BACKGROUND OF THE INVENTION

### 1. Field of the Invention

The present invention relates to chemical test equipment in general, and more specifically to test strip readers.

### 2. Description of the Background

Test strips are a well-known media to test for the presence of particular chemical species in the air, pools, smoke stacks, water, and the like. These test strips are typically single-use disposables and/or consumables provided in bulk a container, typically a plastic vial with removable or flip-top cap.

For example, pool maintenance requires periodic regular testing of pool water and careful maintenance by chemical additives. The testing and balancing of swimming pool water can be a difficult process for the owner. There are myriad test kits available with different capabilities. At minimum a suitable test kit will test for available chlorine, cyanuric acid, pH, total alkalinity, and calcium hardness. Reagent test strips are a very common testing modality. Water test strips usually have a plurality of reagent test areas, each test area undergoing a color change in response to contact with a particular chemical constituent. The presence and concentrations of these constituents of interest can be determined by a colorimetric analysis of the color changes undergone by the test strip. Usually, this analysis involves a color comparison between the test area or test pad and a color standard or scale.

A variety of conventional test strip reading instruments exist which can determine the color change of a test strip.

U.S. Pat. No. 6,614,530 to Duez et al. (Biophotonics S.A.) issued Sep. 2, 2003 shows a method for the colorimetric measurement of a defined region on an image using a color camera, and discloses color-correction of tristimulus (R, G, B) values by selection of an area within an image in order to correct the imperfection in the homogeneity of the sensor and of the illuminant.

U.S. Pat. No. 5,408,535 to Howard, III et al. (Miles, Inc.) issued 18 Apr. 1995 shows a video test strip reader for evaluating test strips that uses a video imager or camera. The reader is connectable to a computer which choreographs imaging at the proper times and calculates the test results, such as the concentration of the constituents of interest.

U.S. Pat. No. 8,655,009 to Chen et al. (Teco Diagnostics) issued 18 Feb. 2014 shows a method and apparatus for color-based reaction testing of biological materials by capturing, in an uncalibrated environment, a digital image of an exposed test strip, together with an adjacently-located reference color chart or on-strip color chart. The image data specifically representing the individual test pads on the test strip, as well as the reference color blocks on the reference chart, are then located within the captured image, and compared to identify any color matches.

U.S. Pat. No. 8,703,057 to Morris (Hach Co.) issued 22 Apr. 2014 shows an electronic device for analyzing an aqueous solution with a housing configured to receive a single test strip.

U.S. Pat. No. 6,285,454 to Douglas et al. (Mercury Diagnostics, Inc.) issued 4 September 2001 shows an assay system that accurately docks a removable test strip with an optics system including an illumination LED and photodetector.

U.S. Pat. No. 8,142,722 to Morris et al. (Hach Co.) issued 27 Mar. 2012 shows a handheld portable electronic test strip tester.

U.S. Pat. No. 7,339,673 to Roman (Siemens Healthcare) issued 4 Mar. 2008 shows a miniature read head for a photometric test strip reader.

U.S. Pat. No. 8,145,431 to Kloepfer et al. (Advanced Medical Products GmbH) issued 27 Mar. 2012 shows a smart-phone-based body fluid test strip positioner. The test strip positioner positions a test strip in the FOV of the phone's camera lens to permit the camera to capture an image. A light source disposed within the positioner illuminates the analyte containing test strip to facilitate the capture of the image of the test strip. Software in the smart phone performs quantitative analysis.

United States Patent Application 20100254581 by Neeser et al. (Reveal Sciences) published 7 Oct. 2010 shows a method and apparatus for analyzing samples by obtaining an image using any mobile consumer device, storing and transmitting the image to a remote server, analyzing the image using an analysis software on a remote server, and sending the results of the analysis back to the consumer device.

U.S. Pat. No. 7,262,779 to Sones (Applied Vision Company, LLC) issued 28 Aug. 2007 shows a differential imaging colorimeter which utilizes a RGB color camera to provide accurate differential colorimetry.

United States Patent Application 20110275162 by Xie et al. (Alverix, Inc.) published 10 Nov. 2011 shows a low-cost assay test strip reader in which the strip is placed in a shuffle that moves it past a photodetector, which detects an optical signal at a single point. The movement of the test strip with respect to the detector allows it to scan a length of the test strip.

U.S. Pat. No. 9,569,858 to Babcock et al. (Taylor Technologies, Inc.) issued 14 Feb. 2017 shows a cloud-based system for water analysis using test strip readers each configured to obtain a digital image of a reagent test strip, normalize and analyze color information in the digital image by colorimetric analysis, and transmit colorimetric values to a cross-platform cloud-based system for analysis.

The foregoing references are configured to read a test strip and compare it to a fixed reference standard. What is needed is a way to read, reference positions, catalogue/index, calibrate, image, correct and analyze multiple test strips at a time using a single reader.

### SUMMARY OF THE INVENTION

Accordingly, it is an object of the present invention to provide an improved test strip reader capable of reading, indexing, calibrating, correcting and interpreting multiple test strips at a time.

Yet another object is to provide a test strip reader with insertion carriage that makes it possible to load multiple test strips into an imaging station with minimal effort and maximum positional precision.

These and other features and benefits are achieved with an improved test-strip reader with insertion carriage that makes it possible to load multiple test strips into an imaging station with minimal effort and maximum precision. The multi-strip reader uses advanced lighting and imaging technology to make it possible to measure various reagents via multiple strips all at once including, for example, Free Chlorine (1C), total alkalinity (TL), cyanuric acid (CYA), total chlorine (CL), bromine (Br), and total alkalinity (pH) as typical of a pool or spa, thereby providing faster, more accurate, and more affordable test results. It maximizes ease and efficiency of use and minimizes risk of user error.

The insertion carrier loads a plurality of test strips at once to the imaging station, and the system automatically identifies them, references their positions, catalogues/indexes them, calibrates them, images them and analyzes them. The apparatus makes the loading and imaging process simple and foolproof for the user by a combination of hardware and software. The hardware employs a roller carriage with pneumatic spring-assist insertion and ejection. The carriage includes a test platform with a plurality of imaging beds to seat and position the strips, and a clamping mechanism to affix them therein. When the user places the test strips in the clamping mechanism and then in the carriage and initiates inward insertion into the enclosure, the remainder of the imaging and analysis process is completed automatically with an internal imaging assembly. The apparatus makes it possible to measure various reagents via multiple strips, up to eleven (11) tests in one minute including:
Free Chlorine 0-10 ppm
Total Chlorine/Bromine 0-10 ppm
pH 6.4-8.4
Total Alkalinity 0-240 ppm
Total Hardness 0-800 ppm
Cyanuric Acid 0-300 ppm
Salt 0-5000 ppm
Borate 0-100 ppm
Copper 0-3.0 ppm
Iron 0-5.0 ppm
Phosphate 0-3000 ppb

For a more complete understanding of the invention, its objects and advantages, refer to the remaining specification and to the accompanying drawings.

### BRIEF DESCRIPTION OF THE DRAWINGS

Other objects, features, and advantages of the present invention will become more apparent from the following detailed description of the preferred embodiments and certain modifications thereof when taken together with the accompanying drawings in which:

FIG. 1 shows a top perspective view of a multiple test strip reader according to an embodiment of the invention.

FIG. 2 is an enlarged perspective view of the carriage 124.

FIG. 3 is an enlarged top view of the test platform 140.

FIG. 4 is a detailed view of a portion of clamp assembly 150.

FIG. 5 is an enlarged perspective view of the roller tray 126 for guided insertion into imaging enclosure 122.

FIG. 6 is a perspective view of the imaging unit 80.

FIG. 7 is a front view of the microcontroller circuit board 40.

FIG. 8 is a photograph of the composite image of four test strips.

FIG. 9 is a block diagram of the imaging and analysis process.

FIG. 10 is a graph of the 7-way pH color calibration curves

FIG. 11 is an example report of the statistically-enhanced color values uploaded and cataloged at step 460.

FIG. 12 is a photograph of the clamp assembly 150 showing how a set of test strips is arranged into clamp assembly 150.

FIG. 13 is a photograph of water vial 166 in use with clamp assembly 150.

FIG. 14 is an exemplary loading fixture 138 shown holding a plurality of test strips 134 such that clamp assembly 150 can be slid over and clamp the protruding ends of test strips 134.

### DETAILED DESCRIPTION OF THE PREFERRED EMBODIMENTS

The present invention is multiple test strip reader configured to read a plurality of test strips at once and automatically identify them, reference their positions, catalogue/index them, calibrate them, image them, and analyze them, all with a single imaging unit. The device makes the loading and imaging process for multiple strips simple and foolproof for the user, allowing simultaneous measurement of various reagents via multiple strips. The multiple test strip reader employs a roller carriage with pneumatic spring-assisted insertion and ejection. The carriage includes a test platform with a plurality of imaging beds, one bed for each test strip, and a clamping mechanism to affix them therein. When the user places the test strips in the carriage with the clamping mechanism and initiates inward insertion into the enclosure, the remainder of the imaging and analysis process is completed automatically with an internal imaging assembly. The apparatus makes it possible to measure various reagents all at once including, for example, Free Chlorine (FC), total alkalinity (TA), cyanuric acid (CYA), total chlorine (TC), bromine (Br), Borate (Bo), Salt, Phosphate (PO4), Iron (Fe) and Copper (Cu), total hardness (TH) and pH as typical of a pool or spa. It maximizes ease and efficiency of use and minimizes risk of user error. For descriptive purposes the following components are given the following reference numerals in the FIGs:

| Ref. | | Ref. | |
|---|---|---|---|
| No. | Component | [symbol] | Component |
| 2 | Multi-strip reader | 133 | Imaging beds |
| 10 | Enclosure | 134 | Test strips |
| 12 | Floor | 138 | Loading fixture |
| 14 | Upright section/chassis | 140 | Test platform |
| 16 | Top panel | 142 | Test beds |
| 22 | Wells | 143 | Guide posts |
| 24 | Wells | 144 | Platform |
| 32 | Illumination circuit board | 145 | Raised end posts |
| 40 | Microcontroller circuit board | 147 | Red positioning strip |
| 48 | Remote connector | 150 | Spring clamp assembly |
| 50 | Indicator panel | 151 | Lever |
| 52 | Openings | 152 | Spring |
| 80 | Cmos camera | 153 | Base |
| 81 | Indicator light | 154 | Pin |
| 83 | Light board | 156 | Carbon steel |
| 87 | Diffusers | 157 | Recesses |
| 121 | Extended tongue | 159 | Hinges |
| 122 | Imaging enclosure | 167 | Magnet |
| 124 | Rolling carriage | 165 | Water sample |
| 126 | Roller tray | 166 | Vial |
| 127 | Rails | 171 | Suction cups |
| 128 | Top shroud | 261 | Track |
| 129 | Bottom tray | 263 | Fixed flange |
| 131 | Raised flange | 264 | Catch |
| 132 | Apertures | 265 | Latch mechanism |
| 133 | Imaging beds | 266 | Gas spring |
| 134 | Test strips | 302 | Color calibration reference |
| 135 | Post | 304 | Grayscale references |
| 138 | Loading fixture | 402 | Microcontroller |
| 139 | Calibration label | 404 | USB connector |
| | | 406 | White LEDs |

[symbol]

indicates data missing or illegible when filed

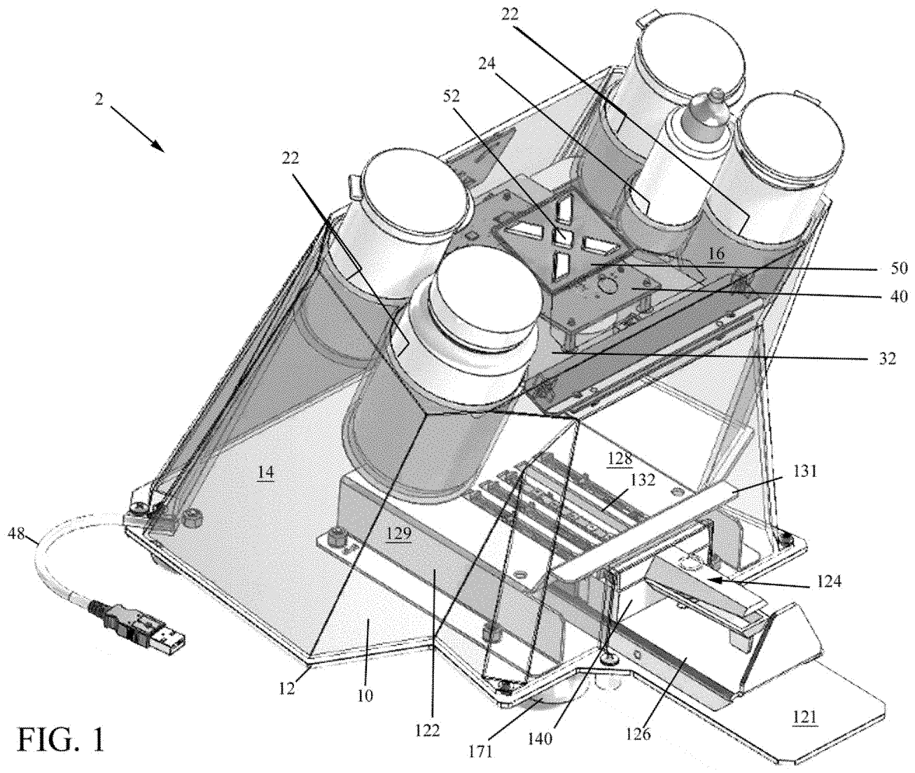

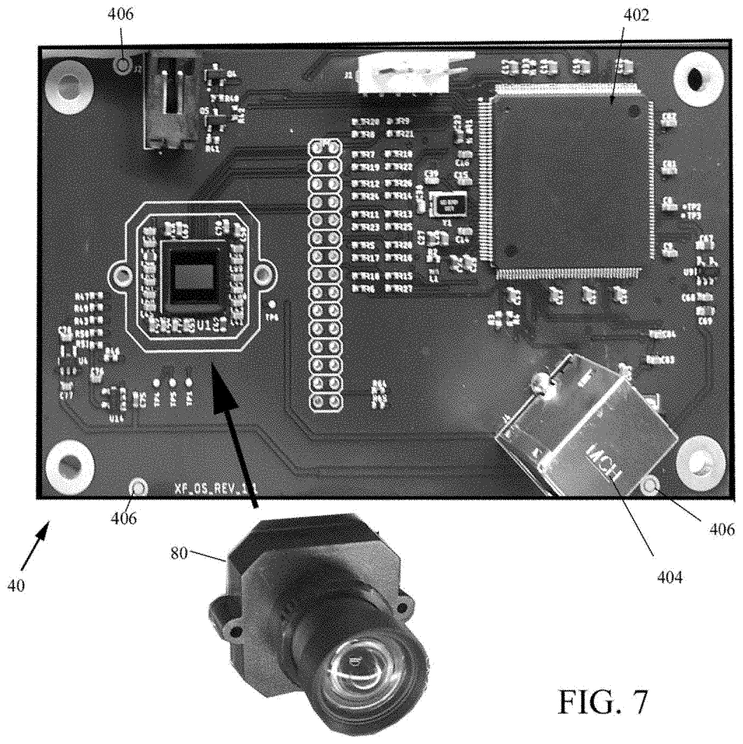

FIG. 1 shows a top perspective view of a multiple test strip reader 2 according to an embodiment of the invention. The multi-strip reader 2 generally comprises an enclosure 10 including a flat horizontal floor 12 secured to a work surface or table by four (4) corner-mounted suction cups 171, and a forwardly-canted upright section 14 presenting an inclined top panel 16. The top panel 16 is inclined at approximately a 30-degree angle so that when the multi-strip reader 2 is positioned atop a table, top panel 16 presents a flat yet frontally-inclined frontal exposure to a person standing directly in front. The top panel 16 is interrupted by a plurality of wells 22, 24 all comprising cylindrical recesses. Several wells 22 are shaped to conform to test strip vials (four being typical) and seat the containers within which the various types of unexposed test strips are provided. One or more wells 24 are shaped to conform to reagent bottles (two being typical) and seat the containers within which the various reagents are provided. The wells 22, 24 flank opposing sides of the top panel 16 and present a center space. An illumination circuit board 32 is suspended below the top panel 16 within the center space, also inclined at an angle, such that it is parallel to horizontal floor 12. The illumination circuit board 32 defines an electronics compartment within which a microcontroller circuit board 40 is mounted atop pylons. A color CMOS camera 80 is mounted to the underside of circuit board 40 (as shown by arrow in FIG. 7). One skilled in the art will understand that a CCD or other known or unknown digital imaging device could be used as well in place of CMOS camera 80. The microcontroller circuit board 40 contains an indicator light 81, in this case an LED, that is on the opposite side of circuit board 40 from CMOS camera 80, and light created by indicator light 81 is visible to the user through translucent indicator panel 50 such that various combinations of color and durations of illumination create specific indications to a person standing directly in front regarding the status of the device. The microcontroller circuit board 40 is also connectable via remote connector 48, here a universal serial bus (USB) connector, to any remote computer. All control inputs and imaging outputs to/from the microcontroller circuit board 40 are communicated via remote connector 48.

Referring back to FIG. 1, the floor 12 includes an extended tongue 121 that provides a runway for a rolling carriage 124. The color CMOS camera 80 mounted to the underside of circuit board 40 is oriented downward toward and parallel to test strips 134 seated in the rolling carriage 124. The rolling carriage 124 conveys a plurality of test strips inward and outward to/from enclosure 10 atop the extended tongue 121 of floor 12, and positions them in an internal imaging enclosure 122. The carriage 124 is spring-loaded by a pneumatic cylinder (to be described) and retained by a latch (to be described) so that semi-automated opening allows the user to load another set of test strips thereon for imaging. The carriage 124 slides in and out of an imaging enclosure 122 that is affixed to the floor 12 inside main enclosure 10. The top shroud 128 of the imaging enclosure 122 bears an array of parallel apertures 132 that expose the respective test strips to the color CMOS camera 80 mounted to the underside of circuit board 40. In addition, the top shroud 128 of the imaging enclosure 122 bears a calibration array next to apertures 132 that provides both positioning indexing and color calibration for the CMOS camera 80 on circuit board 40. When the consumer places test strips in the carriage 124 and initiates inward reinsertion into imaging enclosure 122, the remainder of the imaging and analysis process is completed automatically with the CMOS camera 80 (to be described).

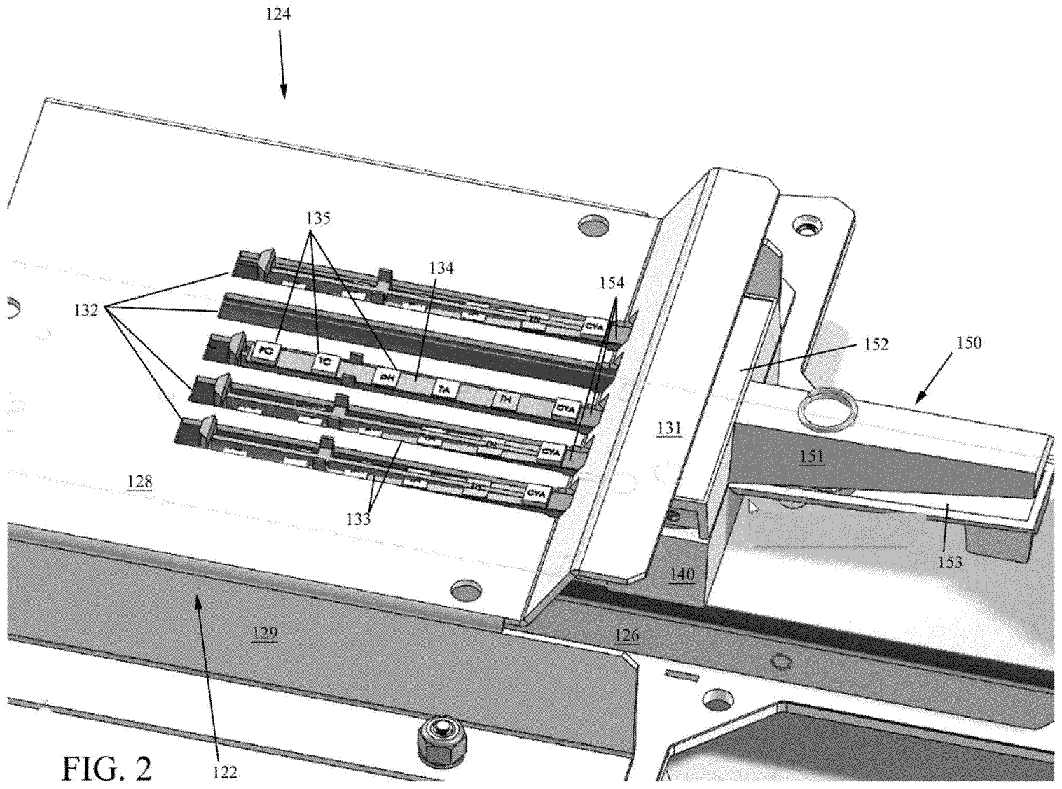

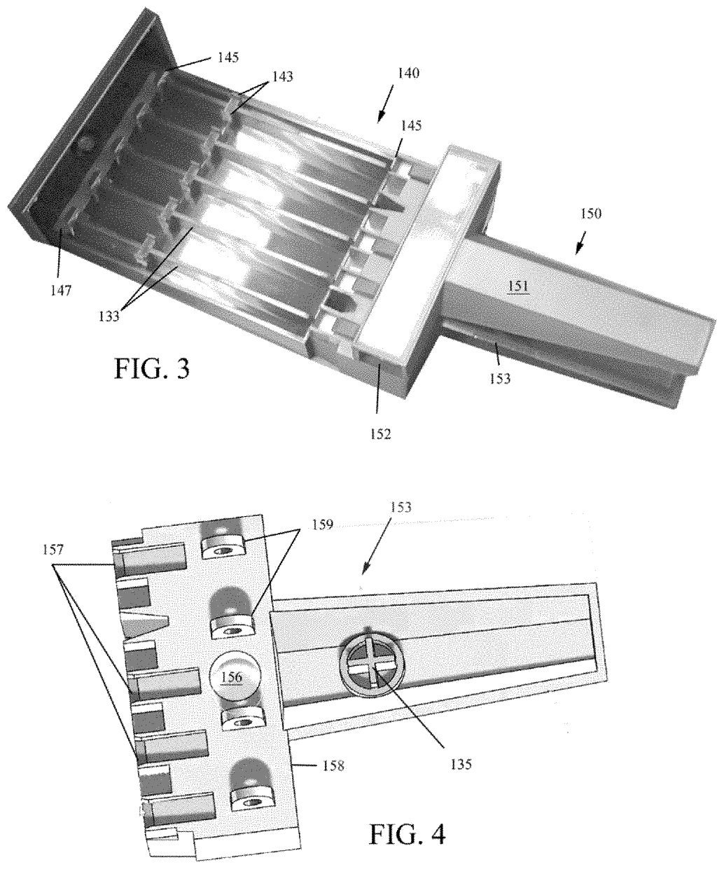

FIG. 2 is an enlarged perspective view of the carriage 124, which includes a roller tray 126 mounted on bearing rollers for guided insertion into imaging enclosure 122. The imaging enclosure 122 includes top shroud 128 attached to bottom tray 129. The top shroud 128 is generally flat and arranged generally parallel to circuit board 40, with a raised flange 131 and a plurality of elongate apertures 132 passing through the top shroud 128 and extending along a majority of the top shroud 128. A test platform 140 rides atop the roller tray 126. With additional reference to FIG. 3, the test platform 140 includes a plurality of imaging beds 133 for each test strip and holds the test strips 134 parallel to circuit board 40. The carriage 124 also includes a spring clamp assembly 150 for loading and clamping the respective test strips onto the imaging beds 133. The clamp assembly 150 includes a base 153, and a lever 151 extending to a bridge 152 that is secured to the base 153 by opposing hinges 159. As seen in FIG. 4 a protruding post 135 on base 153 serves as a seat for a spring and as a stop limit when opening clamp 150. The spring exerts a separating force between lever 151 and base 153 to close the bridge 152, which magnetically latches closed vis-a-vis an embedded piece of carbon steel 156 located in base 153 beneath a magnet in bridge 152. The entire clamp assembly 150 is magnetically indexed into the proper position on platform 140 by magnet 167. Alternatively, magnets of opposite polarity could be used, with a magnet replacing the carbon steel element 156 embedded in platform 140.

Movement of the carriage 124 into and out from the imaging enclosures 10, 122 is guided on the roller bearings atop tracks 127 and at the position furthest inside enclosures 10,122 there is a latch mechanism 265 that is of the push to close/push to open variety and secures carriage 124 into the correct position for subsequent imaging of test strips 134.

FIG. 3 is an enlarged top view of the test platform 140 including imaging beds 133 for each test strip. The imaging beds 133 are flanked by raised guide posts 143 and raised end posts 145 for centering the strips. A red positioning strip 147 traverses the imaging beds 132 at the forefront. Referring back to FIG. 1, the red positioning strip 147 remains visible through the apertures 132 at the forefront and provides a positive indication to the CMOS camera 80 of full and correct insertion of roller tray 126 into enclosure 10.

FIG. 4 is a detailed view of the base 153 of clamp 150 which includes a broad rectangular jaw 158 having a plurality of protruding hinges 159 for pivotal coupling to the bridge 152 of lever 151. The jaw 158 is defined by a plurality of rectangular recesses 157 entering sidelong for seating and centering the distal ends of test strips, and the bridge 152 may likewise be formed with forward-projecting fingers that seat into recesses 157 to secure the test strips therein. The hinges 159 are received in complementary hinges on the bridge 152 of lever 153 and secured thereto by a hinge pin acting as a fulcrum and bearing a spring for bias.

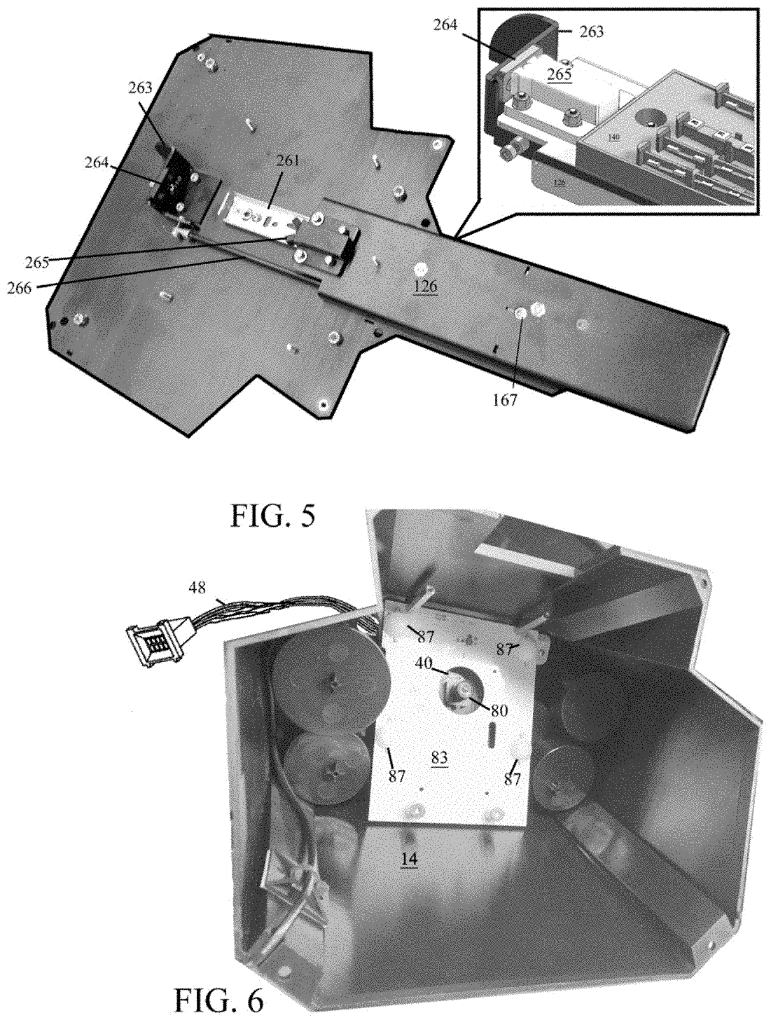

FIG. 5 is an enlarged perspective view of the roller tray 126 mounted on bearing rollers atop tracks 127 for guided insertion into imaging enclosure 122. The roller tray 126 runs along a track 261 into a fixed flange 263 mounted upright on floor 10. A catch 264 projects forward from flange 263 toward the roller tray 126 and a push-latch rebound self-locking cabinet drawer latch mechanism 265 is secured atop roller tray 126 to engage the latch mechanism 264 when the roller tray 126 is fully closed. A gas spring 266 is secured at one end to the flange 263 as shown, and is internally secured at the other end to roller tray 126 to provide a resistance bias thereto.

A CMOS imaging unit 80 is mounted directly above the imaging enclosure 122 for imaging strips. FIG. 6 is a perspective view looking up into the housing 14 of FIG. 1 and showing the microcontroller circuit board 40 mounted therein, suspended atop a light board 83. The CMOS camera 80 is surface-mounted to the microcontroller circuit board 40 and protrudes downward through a portal in light board 83, exposed directly to the sampling tray 140 there beneath. The microcontroller circuit board 40 is connectable via remote USB connector 48 to any remote computer for control and sampling. The opposite side shown the microcontroller circuit board 40 bears at least one multi-color LED light 81 that shines back up through panel 50 of FIG. 1. The LEDs are positioned directly beneath the indicators 52 of FIG. 1 and provide the illumination therefor, thereby providing sequential guidance and status to a person standing directly in front.

Specifically, the LEDs/indicator lights 81/52 flash green, yellow or red. In addition, the light board 83 bears four (4) white LEDs that shine into light diffusers 87 as shown, which in turn directs white light down toward the test strips for illumination thereof. The LED diffusers 87 help “smooth out” the light and minimize “hot spots”. The four diffusers 87 are translucent white frosted hemispherical panels and are fixed to light board 83 and used to spread light from the LEDs evenly inside the chassis 14.

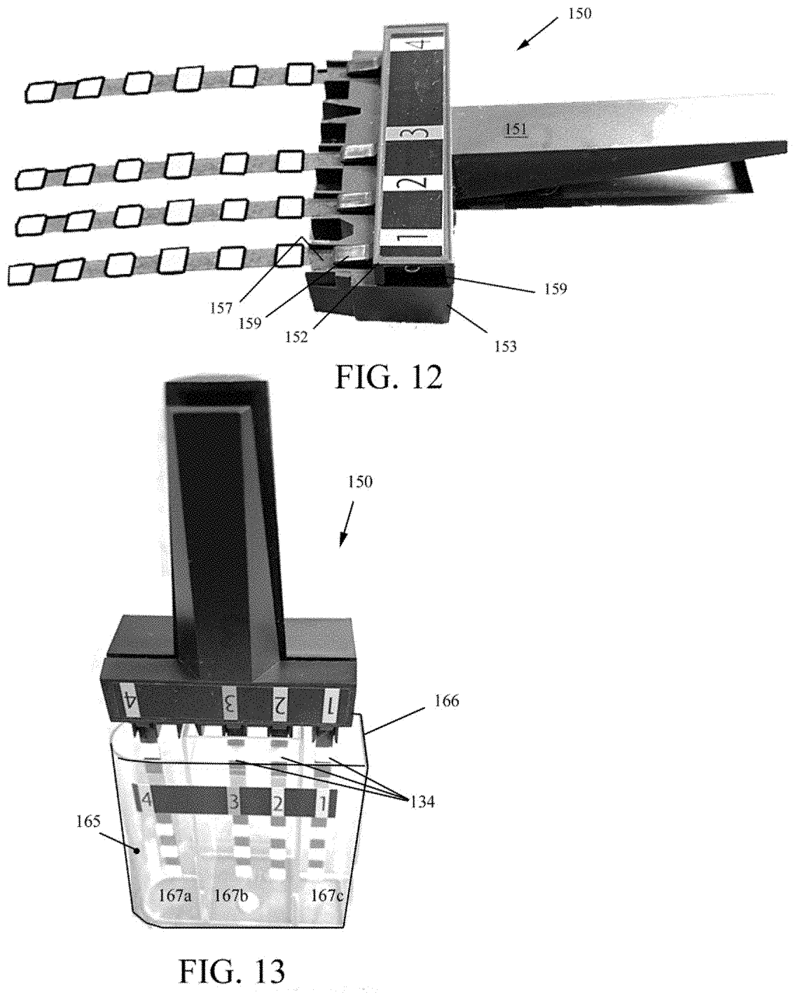

FIG. 12 shows how a set of test strips is loaded and clamped in place with clamp assembly 150.

A user would then take clamp assembly 150 that is properly loaded with test strips 134 (FIG. 12) and dip the strips simultaneously into a water sample.

FIG. 13 illustrates how the entire clamp assembly 150 fully loaded with test strips 134 is dipped into a specialized vial 166 containing a water sample 165. Sample water 165 will be absorbed into pads 135 of test strips 134 and then the user removes clamp assembly 150 with the wetted test strips. Preferably, the sample water 165 that is contained within water sample vial 166 is segregated into a plurality of discrete chambers 167a-c so that a reagent or dye from one test strip 134 is isolated and does not affect the other test strips 134 or if the sample water 165 in a chamber is pre-treated for a particular analyte, this pre-treatment will not affect sample water 165 in other chambers.

After sampling, the user is then places clamp assembly 150 into place on rolling carriage 124 atop roller tray 126 such that clamp 150 is properly located and inserts the carriage 124 into imaging enclosure 122 until latch mechanism 265 engages with and holds catch 264, at which point the test strips lie directly in the field of view of the illuminated CMOS camera 80 for full frontal illumination and imaging. In this imaging position the CMOS imager 80 images the strips without substantial glare interference to or from the illumination. The remote computer runs a software application that automatically triggers a still image frame from the CMOS imager 80. This image includes all strips and test strip pads on the strip, as well as a calibration label 139 (FIG. 2), and it is subjected to registration, calibration and colorimetric analysis as will be described. At the conclusion of the testing sequence the user pushes carriage 124 slightly further into enclosure 10 which activates the release cycle of latch mechanism 265. Alternatively, it is contemplated to use magnetic latches or a variety of other well know latching mechanisms to accomplish the securing of carriage 140 in the correct position for imaging of test strips 134. Once carriage 124 is fully extended, clamp assembly 150 can be removed from the system by the user and strips 134 are unclamped by squeezing lever 151 towards base 153 and then the user may dispose of the used test strips 134.

FIG. 7 is a front view of the microcontroller circuit board 40 which is built around an ARM™ general purpose 32 bit surface-mount microcontroller 402 and a lensed mini-camera module 80 mounted on one side, along with a 3.6V power supply and all associated componentry. The CMOS camera 80 may, for example, be a two-megapixel color image sensor with 10× magnification lens and built-in infrared filter (visible light only), a variety of which are commercially available (e.g., Arduino™). The microcontroller circuit board 40 includes reinforced corner holes for pylon suspension from the top (FIG. 6). On light board 83 white LEDs 406 are mounted to provide illumination for camera 80. Referring back to FIG. 6 these white LEDs 406 shine downward from light board 83, and through hemispherical diffuser lenses 87 attached to light board 83 for illumination of the sampling tray 140 there beneath. On the flipside of circuit board 40 there is at least one RGB LED mounted directly beneath the segments 52 of the indicator panel 50 (FIG. 1) for selective illumination thereof in a desired color (red, green, blue or white). This allows color-coded/directional guidance to the operator.

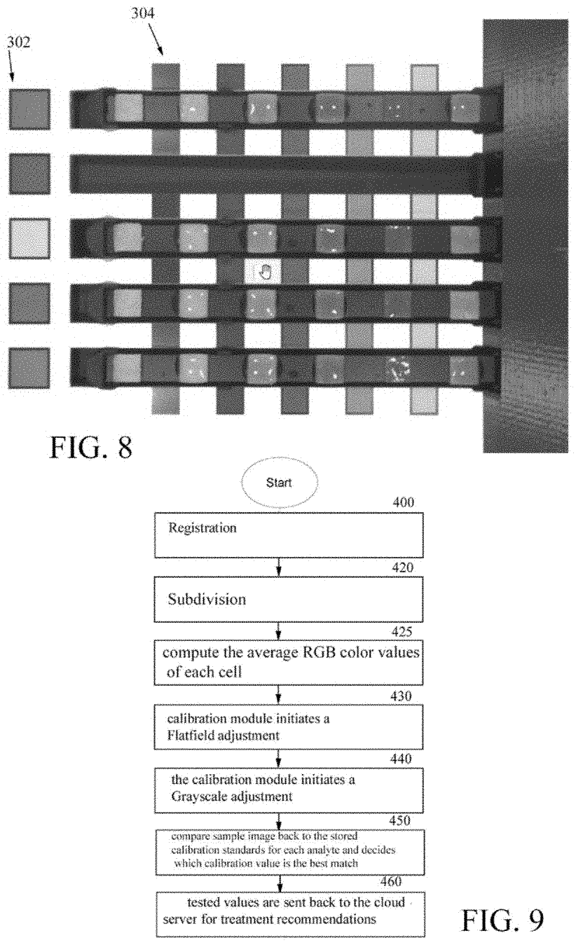

FIG. 8 is a photograph of the composite image of four test strips taken by the camera 80 while seated in imaging beds 133 (shown at rows 1 and 3-5) and a permanent calibration pattern on calibration label 139 printed or laminated atop the top shroud 128 of the imaging enclosure 122 (FIG. 2). The permanent calibration reference 139 includes both a color calibration reference 302 comprising a transverse array of calibrated color swatches for RGB calibration, plus a series of transverse greyscale color references 304 ranging from dark to light for brightness calibration. The combination of test strips 134 typically includes but is not limited to pads for Total Alkalinity (0, 40, 80, 120, 180, 240 ppm); Free Bromine (0, 2, 4, 6, 10, 20 ppm) or Free Chlorine (0, 1, 2, 3, 5, 10 ppm); Total Chlorine (1, 0.5, 1, 2, 5, 10 ppm); Cyanuric Acid (0, 40, 70, 100, 150, 300 ppm); Hardness (0, 100, 200, 400, 800 ppm); Salt (0, 1000, 2000, 3000, 4000, 5000 ppm), Iron (0, 0.3, 0.6, 1.0, 3.0, 5.0 ppm); Copper (0, 0.3, 0.6, 1.0, 3.0 ppm); Borate (0, 15, 30, 50, 75, 100) Phosphate (0, 500, 1000, 2000, 3000 ppb); and pH (6.4, 6.8, 7.2, 7.5, 7.8, 8.4). The strips are imaged sequentially according to a schedule of optimal exposure times ranging from 20-60 seconds after the strips are dipped in water sample 165. All images include at least test strips 134 and calibration reference(s) 134 and all are outputted to a remote computer for registration and colorimetric analysis. From the outputted image frames, a remote software application is able to automatically verify strip position and orientation, index and identify each strip, divide each pad into a grid array of panels, compute the color for each pad 135, apply calibrations and display/output the results for the value of each chemical analyte. The remote computer/server may also return treatment recommendations including recommended chemical levels and identification of the proper chemical products to purchase for attaining those levels.

FIG. 9 is a block diagram of the imaging and analysis process. At step 400 the software begins with registration: locating the test strips in the captured image; analyzing the image to determine which strips are present; indexing the positions of each strip; and assigning a unique ID to each imaged test strip and sub-ID for each pad.

At step 420 the software sub-divides each pad into a checkerboard array of sub-areas. Given a subdivided image the software performs an image analysis on each cell.

At step 425 a calibration module employs an averaging sequence across the subdivided cells to account for and calculates a mean value for the cell. The imaging process is inherently prone to pixel variance across each sample region and the averaging process smooths the variance. This mean is used as the sample value for that subcell.

At step 430 the software initiates a flatfield adjustment to account for lighting variations within a given picture. Flatfield adjustments for all subcell regions are calculated from white-only calibration regions of the calibration row. The flatfield adjustment assumes that these areas should be “white”, and compensates for any variation.

At step 440 the software initiates a Grayscale adjustment using the permanent greyscale calibration references 304 to account for variation in image-capture-hardware (RGB/gamma distribution/etc.), aging of ambient lighting, etc.

At step 450 the calibration module compares the sample image back to the calibration standards stored in the program for each analyte and decides which calibration value is the best match for the sample image.

Finally at step 460 the color values computed for each test pad 135 are uploaded and cataloged, and every correction that was applied is uploaded and cataloged by device in a test history for the device. The test history for the device is monitored over time to provide drift alerts of the color values of reference colors 302 and 304 to the user.

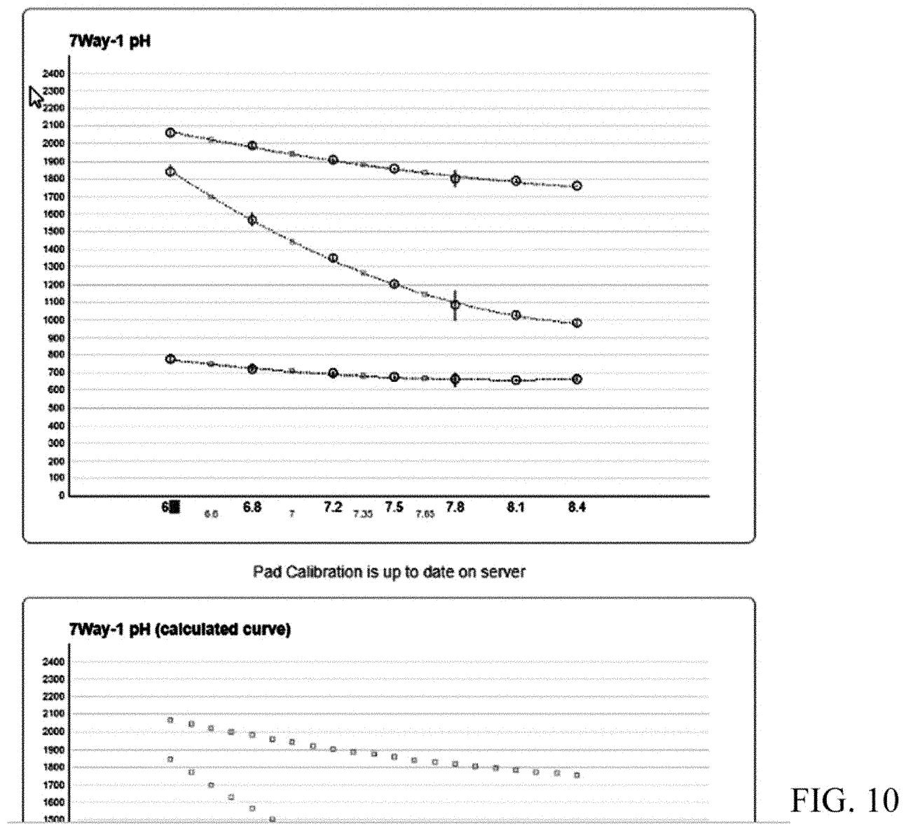

FIG. 10 is a graph of the 7-way pH color calibration curve of pH value versus pixel value for red, green and blue channels.

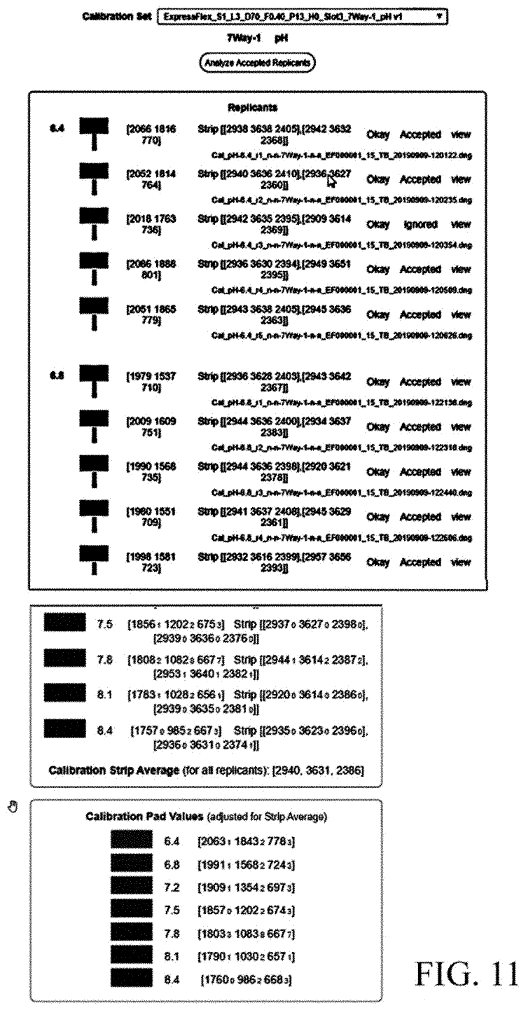

FIG. 11 is an example report of the details of the color values used to create the calibration curve in FIG. 9.

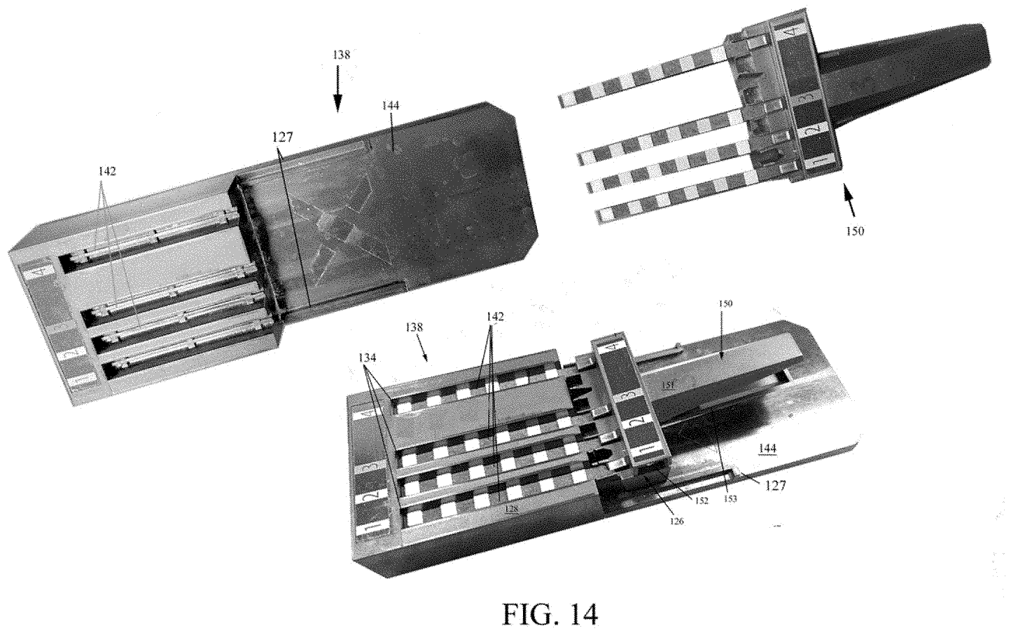

FIG. 14 is photograph depicting an exemplary loading fixture 138 for loading a plurality of test strips 134 into the clamp assembly 150 simultaneously. The loading fixture 138 is similar to test platform 140 and includes a plurality of test beds 142 for each test strip 134. The test beds 142 are spaced equal to the jaws of clamp assembly 150 and are slightly shorter than the test strips 154. This way, the parallel beds 142 hold the test strips 134 parallel in position with their distal ends protruding outward from the beds 142 ready to be clamped by clamp assembly 150. Loading fixture 138 also includes a platform 144 leading to the test beds 142, and a pair of raised rails 147 extending across the platform 144 toward test beds 142 for guiding clamp 150 there across. In use, as shown in the lower inset of FIG. 14, the loading fixture 138 holds a plurality of test strips 134 oriented such that clamp assembly 150 can be slid along platform 144 and clamp the protruding ends of test strip 134, thus having all test strips 134 properly oriented for wetting with sample water 165 and placing onto carriage 124 for imaging once inserted into strip reader 2.

It should now be apparent that the above-described multi-strip reader provides a platform for more efficient reading, indexing, calibrating, correcting and interpreting multiple test strips at a time. It makes it possible to load multiple test strips into an imaging station with minimal effort and yet maximum positional precision.

Having now fully set forth the preferred embodiments and certain modifications of the concept underlying the present invention, various other embodiments as well as certain variations and modifications of the embodiments herein shown and described will obviously occur to those skilled in the art upon becoming familiar with said underlying concept. It is to be understood, therefore, that the invention may be practiced otherwise than as specifically set forth in the appended claims.

We claim:

1. A test-strip reader, comprising:
an enclosure having an entryway;
a CMOS imager housed inside the enclosure;
a carriage mounted on a plurality of rollers for insertion into said entryway, said carriage having a plurality of imaging beds to seat and position individual test strips, and
a clamping mechanism to affix said test strips in said imaging beds.

2. The test-strip reader according to claim 1, wherein said carriage is indexed in position beneath said CMOS imager.

3. The test-strip reader according to claim 1, wherein said carriage has five imaging beds to seat and position five individual test strips.

4. The test-strip reader according to claim 1, wherein said carriage comprises integral calibration colors.

5. The test-strip reader according to claim 1, further comprising a water sample container comprising a plurality of separate but adjacent water chambers.
